(19) United States
(12) Patent Application Publication
(10) Pub. No.: US 2008/0211114 A1
(43) Pub. Date: Sep. 4, 2008

(54) SEMICONDUCTOR COMPONENT

(76) Inventors: Fred Liebermann, Radebeul (DE); Axel Pannwitz, Radebeul (DE)

Correspondence Address: Muncy, Geissler, Olds & Lowe, PLLC, P.O. BOX 1364, FAIRFAX, VA, 22038-1364, US

(21) Appl. No.: 11/957,347

(22) Filed: Dec. 14, 2007

Related U.S. Application Data
(60) Provisional application No. 60/875,376, filed on Dec. 18, 2006.

(30) Foreign Application Priority Data
Dec. 16, 2006 (DE) DE 102006059534.3

(51) Int. Cl. H01L 23/49

(52) U.S. Cl. 257/784; 257/E23.024

(57) ABSTRACT

A semiconductor component is provided, particularly for LIN bus systems, having an integrated circuit, which on a top side has a plurality of terminal pads for coupling and/or decoupling of electrical signals, and having a plurality of electrically conductive contact reeds, which are electrically connected at least partially by connecting bonding wires to the respectively assigned terminal pads of the integrated circuit. Also, a connecting bonding wire and a shielding bonding wire is provided, which is disposed with both ends on a uniform electric potential, particularly on one of the contact reeds.

This nonprovisional application claims priority to German Patent Application No. DE 102006059534, which was filed in Germany on Dec. 16, 2006, and to U.S. Provisional Application No. 60/875,376, which was filed on Dec. 18, 2006, and which are both herein incorporated by reference.

### BACKGROUND OF THE INVENTION

1. Field of the Invention

The present invention relates to a semiconductor component having an integrated circuit, which on a top side has a plurality of terminal pads for coupling and/or decoupling electrical signals, and having a plurality of electrically conductive contact reeds, which are electrically connected, at least partially, by connecting bonding wires to the respectively assigned terminal pads of the integrated circuit.

2. Description of the Background Art

Conventional semiconductor components are known from the market and can be formed in many different ways as a processor, memory, control device, etc., for integration into an electronic circuit. The semiconductor component is formed substantially of an integrated circuit, which is realized as an array of electronic structural components such as transistors, resistors, capacitors, etc., on a semiconductor crystal. For electrical coupling of the integrated circuit to an electronic circuit, which can be made in particular as a printed circuit board populated with discrete electronic components, a plurality of electrically conductive contact reeds are assigned to the integrated circuit. Contact reeds are also called lead strips or leadframes and are typically structures etched or stamped from a thin sheet. The contact reeds can be formed as contact pins for mounting in corresponding holes in the printed circuit board; they can also be realized as contact reeds for surface mounting (surface mount device/SMD) or for a ball grid array (BGA). Other structural forms of semiconductor components can be formed as chip-on-board or as a ball grid array. In structural forms of this type, the integrated circuit is not placed on a leadframe, but on a printed circuit board provided on one or both sides with traces, optionally with through-hole platings, whereby suitably formed regions of the traces serve as contact reeds.

Bonding wires, extending from the terminal pads of the integrated circuit to the contact reeds, are provided for electrical contact between the integrated circuit and the contact reeds. The bonding wires typically run substantially parallel to one another or are applied to the integrated circuit projecting radially circumferentially.

To assure reasonable handling of the semiconductor component during production of electronic circuits, the integrated circuit together with the bonding wires and the contact reeds are taken up in a plastic potting compound in such a way that only the contact reeds project in areas from the potting compound and can be used for the electrical contacting of the semiconductor component. The other parts of the semiconductor component, such as the integrated circuit on the semiconductor crystal and the bonding wires, are sealed in the form-stable potting compound. During use of printed circuit boards, suitably formed contact areas of the printed circuit board project from the potting compound and thus enable an electrical connection to other circuit parts.

Integrated circuits in the meantime have a high integration density, therefore a large number of electrical circuit components in a small space, and therewith also require a high density of terminal pads and the respectively assigned bonding wires. Because high-frequency electrical signals are also transmitted to or from the integrated circuit through the bonding wires, a mutual influence on the electrical signals by inductive interactions can occur between neighboring bonding wires. Interference radiation of this type can be coupled at different sites within the integrated circuit via the internal electrical lines provided in the integrated circuit and therefore can lead to undesirable interference in several places in the integrated circuit.

This is important particularly in integrated circuits in which shielding against interference radiation and interfering signals is to be provided at low cost, to be able to realize a cost-effective construction. An electronic circuit of this type can be realized for use, for example, with a LIN bus (Local Interconnect Network), which is a fieldbus. The LIN bus was developed especially for the cost-effective communication by intelligent sensors and actuators in motor vehicles. Typical application examples for a LIN bus are networking within a door or a seat for motor vehicles. The LIN standard is used wherever the bandwidth and versatility of CAN (Controller Area Network) are not needed.

### SUMMARY OF THE INVENTION

It is therefore an object of the present invention to reduce the interference susceptibility of a semiconductor component by simple means.

According to the invention, the semiconductor component is formed in such a way that adjacent to a connecting bonding wire a shielding bonding wire is provided, which is disposed with both ends on a uniform electric potential, particularly on one of the contact reeds. The shielding bonding wire has the task of keeping away or at least partially damping the interference radiation of an adjacently disposed second connecting bonding wire (signal bonding wire/reference potential bonding wire), which is supplied with high-frequency electrical signals, from a first connecting bonding wire or, conversely, also of at least partially or completely damping the interference radiation of the first connecting bonding wire. This is achieved in that the high-frequency electrical interfering signal, which is sent by the second connecting bonding wire, is coupled inductively into the shielding bonding wire and there induces a voltage. Because the shielding bonding wire is disposed between the second connecting bonding wire, emitting the interference radiation, and the first connecting bonding wire, to be shielded, and a uniform electric potential is applied at both of its ends, it forms a short-circuited winding for the induced power. In other words, the electromagnetic field emitted by the second connecting bonding wire is coupled at least proportionally inductively into the shielding bonding wire and short-circuited there. Therefore, the shielding bonding wire acts as a short-circuit winding for the high-frequency electrical interfering signal and converts the radiated electromagnetic field into heat.

As a result, the shielding bonding wire is capable of absorbing a considerable portion of an electromagnetic field coming from the high-frequency electrical interfering signal and thereby of reducing the interference radiation onto the adjacent bonding wire. This assures improvement in integrated circuit function, because interference radiation, particularly in reference potential lines or reference potential networks, can be reduced.

The surprising effect of the invention is that an additional shielding bonding wire, clamped with both ends at a uniform electric potential, as a short-circuit winding is capable of significantly reducing interference radiation on adjacent bonding wires.

An embodiment of the invention provides that the shielding bonding wire and the connecting bonding wire are disposed on a mutual contact reed. Thus, a small distance between the shielding bonding wire and the connecting bonding wire can be selected, as a result of which an advantageous inductive coupling of the bonding wires can be achieved. This assures, moreover, that the connecting bonding wire and the shielding bonding wire are at the same, uniform electric potential.

It is provided in another embodiment of the invention that the shielding bonding wire at least in sections runs within outer cylinder sections, which are disposed concentrically around the reference potential bonding wire and have radii that are at most 6 times that of the bonding wire radius, preferably at most 4.5 times that of the bonding wire radius, especially preferably at most 3.5 times that of the bonding wire radius. The outer cylinder sections in each case describe cylindrical regions around the reference potential bonding wire, whereby a center of each outer cylinder section is disposed coaxially to the reference potential bonding wire and whereby the shielding bonding wire with its entire diameter is taken up in the outer cylinder section. The division of the outer cylinder sections can be varied in such a way that the entirety of the outer cylinder sections forms a type of tubular geometry or sheathing tube around the reference potential bonding wire, whereby the course of a central axis of the sheathing tube corresponds to the course of the central axis of the bonding wire. The individual outer cylinders each have a radius adjusted to a multiple of a typically constant radius of the bonding wire. A typical gold bonding wire has a radius between 0.0125 mm and 0.025 mm, so that the outer cylinder sections may have a maximum radius of 0.075 mm to 0.15 mm. This means, for example, that a distance, i.e., a minimal distance, between a surface of the reference potential bonding wire and a surface of the shielding bonding wire is 0.05 mm at a bonding wire radius of 0.025 mm and 5 times greater outer cylinder radius.

Another embodiment of the invention provides that the shielding bonding wire runs at least over 50% of its length, preferably over at least 75% of its length, especially preferably over at least 85% of its length within the outer cylinder sections of the connecting bonding wire. Regarded as the length of the shielding bonding wire is the dimension along the bonding wire between the two bonding connections with the uniform electric potential. End regions of the shielding bonding wire, projecting beyond this, as they may occur in wedge bonds, are not considered for the length of the shielding bonding wire. The advantageous shielding effect for the connecting bonding wire is increased with an increasing length of the shielding bonding wire, which runs within the outer cylinder sections of the connecting bonding wire. It is especially advantageous when the shielding bonding wire lies within the outer cylinder sections of the connecting bonding wire over at least 50%, preferably over at least 75%, especially preferably over at least 85% of the length of the connecting bonding wire.

It is provided in another embodiment of the invention that a first bonding connection of the shielding bonding wire is disposed directly adjacent to a bonding connection of the shielding bonding wire, particularly in a surrounding area around the connecting bonding wire with a radius smaller than a 6-fold bonding wire radius. An advantageous shielding effect can be assured by a distance as small as possible between the shielding bonding wire and the connecting bonding wire. In an especially preferred embodiment, the radius of the surrounding area, whose center point is disposed centrically to the bonding connection of the connecting bonding wire and which completely encompasses the shielding bonding wire, is smaller than a 4-fold bonding wire radius. This can be achieved in particular when both adjacent bonding connections are made as wedge bonds, therefore as bonding connections only slightly broadened compared with the bonding wire. In an especially advantageous embodiment, the shielding bonding wire is bonded on a conventional contact reed beside the connecting bonding wire. Therefore, to realize the advantageous shielding, no change in the geometry of the contact reeds or the leadframe is necessary and a standard leadframe can be used despite the shielding bonding wires.

Another embodiment of the invention provides that a second bonding connection of the shielding bonding wire is disposed directly adjacent to the integrated circuit, particularly at a distance smaller than 5-fold of the bonding wire radius, at a distance from an outer edge of the integrated circuit. Distance describes the distance between the directly opposite outer edges of the integrated circuit and the shielding bonding wire. Such a selection of the distancing achieves that the shielding bonding wire in the immediate vicinity of a face of the integrated circuit can be routed in the direction of the connecting bonding wire. As a result, the shielding bonding wire and the connecting bonding wire can be run substantially parallel over as long a path as possible.

Another embodiment of the invention provides that the shielding bonding wire proceeding from the bonding wire adjacent to the integrated circuit runs at least almost perpendicular to the reference potential area and is bent at the level of the connecting bonding wire with a small bending radius, particularly at least almost with a minimal bonding wire bending radius, in such a way that it runs substantially parallel to the connecting bonding wire up to the contact reed. This means that the objective can be met in that the shielding bonding wire runs the shortest route from the bonding connection to the connecting bonding wire and from there can be made as long as possible and substantially parallel to the connecting bonding wire. The minimal bonding wire bending radius is determined by the material selection and geometry of the bonding wire and for a gold bonding wire is typically 4-6 times the bonding wire radius.

Another embodiment of the invention provides that an integrated circuit first terminal pad is provided to supply a reference potential to a reference potential line of the integrated circuit and the integrated circuit is applied to an electrically conductive reference potential area, whereby proceeding from a reference potential contact reed, a reference potential bonding wire is routed to the first terminal pad, connected to the first reference potential line; and whereby adjacent to the reference potential bonding wire a shielding bonding wire is provided, which lies with both ends on the electric potential of the reference potential area. This assures an improvement in the function of the integrated circuit, because interference radiation in the reference potential lines can be reduced. The shielding bonding wire is provided in addition to the electrically conductive connection between the reference potential area and the reference potential contact reed. The integrated circuit has trace structures, which are provided to supply the reference potential within the integrated circuit and are designated as reference potential lines. A surface, facing away from the terminal pads, of the integrated circuit typically lies flat on the reference potential area, which is part of the contact reeds or the leadframe and which is also called a “scoop”, die attach pad, or die pad. The reference potential area is connected in an electrically conductive manner to at least one reference potential contact reed.

Another embodiment of the invention provides that the reference potential area and the reference potential contact reed are formed as a single piece. As a result, an especially low impedance between the reference potential area and the reference potential contact reed is assured and the shielding bonding wire forms a short-circuit loop with a low impedance and high absorbability for the coupled electromagnetic signals between the reference potential area and the reference potential contact reed.

It is provided in another embodiment of the invention that the integrated circuit is provided with a plurality of connecting bonding wires, each of which is assigned a shielding bonding wire. Despite the increased number of electrical lines, which are potentially suitable for coupling in interference radiation, a low interference radiation level for the integrated circuit can be assured overall by the use of respectively assigned shielding bonding wires.

Another embodiment of the invention provides that the connecting bonding wire is assigned shielding bonding wires on both sides. A shielding effect for the respective connecting bonding wire can be increased thereby.

It is provided in another embodiment of the invention that proceeding from the reference potential contact reed, two reference potential bonding wires are routed to different reference potential lines of the integrated circuit and that at least one shielding bonding wire runs between the adjacent reference potential bonding wires. The effect of the shielding bonding wire is especially advantageous when both the bonding wire sending out the interfering signal and the bonding wire receiving the interfering signal are at a common reference potential and for reasons of space and/or cost are bonded to the same reference potential contact reed.

When an interfering signal is coupled in one of the two reference potential lines, for example, in the reference potential line assigned to a LIN bus, a massive current flow with a high frequency across the corresponding reference potential bonding wire can occur. In this way, this bonding wire transmits strong interfering signals, which without the shielding bonding wire would be coupled in the almost parallel second reference potential bonding wire and thereby could lead to unwanted interference coupling, which would nullify the original idea of two separate reference potentials (bus and signal ground). Because bus lines in a LIN bus system cannot be blocked easily with filter elements, because this would impede signal transmission to the LIN bus, it must be accepted that the coupled interfering signals flow off across the reference potential line and the reference potential bonding wire. The interference radiation onto the neighboring, second reference potential bonding wire, supplying the second reference potential line, can be minimized by using the shielding bonding wire.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic side view of a semiconductor component having an integrated circuit, a leadframe, and bonding wires;

FIG. 2 shows a schematic plan view of a semiconductor component having an integrally formed connection between the reference potential area and the reference potential contact reed;

FIG. 3 shows a schematic plan view of a semiconductor component having a separately made contact reed section;

FIG. 4 shows a schematic plan view of a semiconductor component having a lengthened contact reed for the shielding bonding wire; and

FIG. 5 shows a schematic plan view of a semiconductor component having a separate contact reed for the shielding bonding wire.

### DETAILED DESCRIPTION

In the following descriptions of the figures, the same reference characters are used for functionally equivalent components.

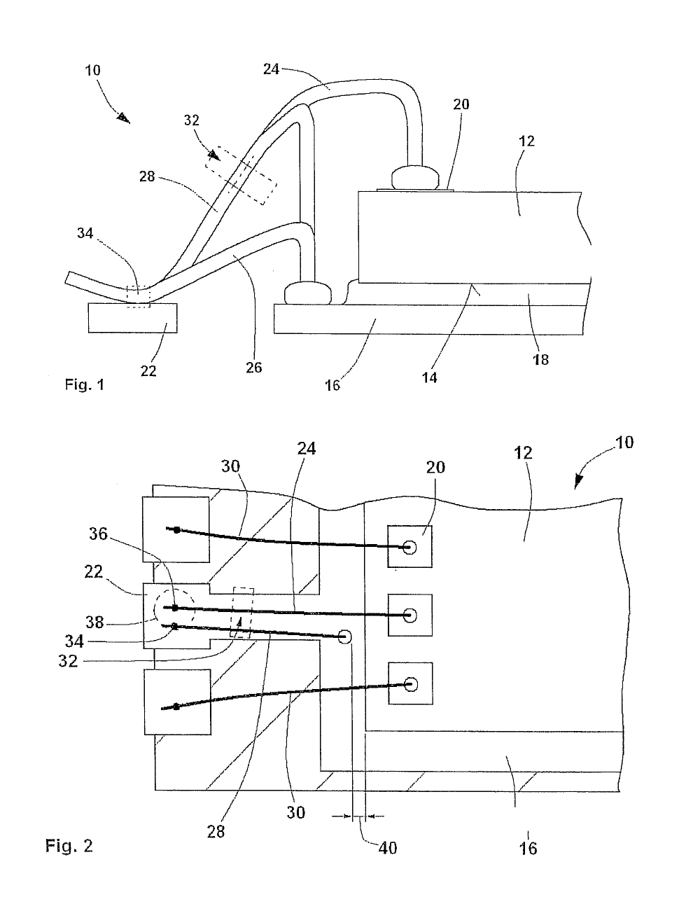

In FIG. 1, in a schematic drawing, a semiconductor component 10 is shown in a side view, whereby the potting compound is eliminated to simplify the drawing in the illustration. An integrated circuit 12 is realized on a silicon substrate with a layer structure, which is not described in greater detail, and is applied with its underside 14 to a reference potential area 16 by means of a conductive adhesive 18. Terminal pads 20, which are configured for an electrically conductive connection to electrically conductive contact reeds 22, are realized on a top side of the silicon substrate. Contact reed 22, shown in FIG. 1, is a reference potential contact reed, provided for coupling an electric reference potential into one or more reference potential lines of integrated circuit 12.

A plurality of bonding wires which sense different functions are shown in FIG. 1. All depicted bonding connections of the bonding wires are made as ball-wedge bonding connections. A reference potential bonding wire 24 is provided for coupling the electric reference potential into a first reference potential line (not shown in greater detail) of integrated circuit 12. A connecting bonding wire 26, which can also be designated as the reference potential bonding wire, produces an electrically conductive connection between reference potential contact reed 22 and reference potential area 16. A shielding bonding wire 28, which is provided in addition to the connecting bonding wire between reference potential contact reed 22 and reference potential area 16, is used to shield reference potential bonding wire 24 from interference radiation of high-frequency electrical interfering signals. For this purpose, shielding bonding wire 28 is placed with both ends on the uniform electric potential of reference potential contact reed 22 and reference potential area 16 electrically connected via connecting bonding wire 26. Thereby, shielding bonding wire 28 forms a short-circuit winding, which makes it possible to absorb inductively coupled signals and to convert them to heat.

The interfering signals can be coupled, for example, via signal bonding wires 30 (not shown in greater detail in FIG. 2), adjacent to reference potential bonding wire 24, into integrated circuit 12 or decoupled from said circuit. Owing to the spatial proximity between bonding wires 24 and 30, unwanted signal coupling of the interfering signal(s) in reference potential bonding wire 24 can occur without shielding bonding wire 28.

For an advantageous mode of action of shielding bonding wire 28, the smallest distance possible between reference potential bonding wire 24 and shielding bonding wire 28 and an at least substantially parallel course of bonding wires 24, 28 are to be realized over a considerable part of the length of bonding wires 24, 28, without bonding wires 24, 28 touching. A length of reference potential bonding wires 24 of approximately 2.1 mm at a bonding wire radius of 0.035 mm is provided in the exemplary embodiments shown schematically in FIGS. 1 and 2, but not to scale. Shielding bonding wire 28 runs for a length of approximately 1.6 mm and thereby, for about 80%, substantially parallel to reference potential bonding wire 24 in its outer cylinder 32.

In the embodiment according to FIG. 1, connecting bonding wire 26 is provided for an electrical connection between reference potential area 16 and reference potential contact reed 22. In the embodiment of FIG. 2, it is provided, however, that reference potential contact reed 22 is attached as a single piece to reference potential area 16. This type of connection of reference potential contact reed 22 is also called “fused-lead” and makes connecting bonding wire 26 unnecessary. As a result, an especially low impedance between reference potential contact reed 22 and reference potential area 16 can be assured.

In FIGS. 1 and 2, an outer cylinder section 32 is shown in each case as an example, which is disposed concentrically around reference potential bonding wire 24. A radius of outer cylinder section 32 is selected so that it is at most 6 times the bonding wire radius. Shielding bonding wire 28 is disposed in such a way that in practice it runs over 75% of its length in outer cylinder section 32 of reference potential bonding wire 24. Reference potential bonding wire 24 is shielded even over about 80% of its length by shielding bonding wire 28. An advantageous damping of radiated interfering signals by shielding bonding wire 28 acting as a short-circuit winding is assured by this spatial proximity of shielding bonding wire 28 to reference potential bonding wire 24.

Moreover, a contact region 34 of the bonding connection of shielding bonding wire 28, shown symbolically in FIGS. 1 and 2, is disposed in such a way in the vicinity of a contact region 36 of the bonding connection of reference potential bonding wire 24 that contact region 34 lies within a surrounding area 38 of contact region 36. Surrounding area 38 has a radius corresponding to 5 times the bonding wire radius.

The ball bond of shielding bonding wire 28 is disposed directly adjacent to integrated circuit 12, whereby a distance 40 of the ball bond to an outer edge of integrated circuit 10 is less than 5 times the bonding wire radius. Shielding bonding wire 28 runs proceeding from the ball bond at least almost perpendicular to underside 14. At the level of reference potential bonding wire 24, shielding bonding wire 28 is bent with a slight bending radius to assure that it can run along the shortest route substantially parallel to reference potential bonding wire 24 up to reference potential contact reed 22.

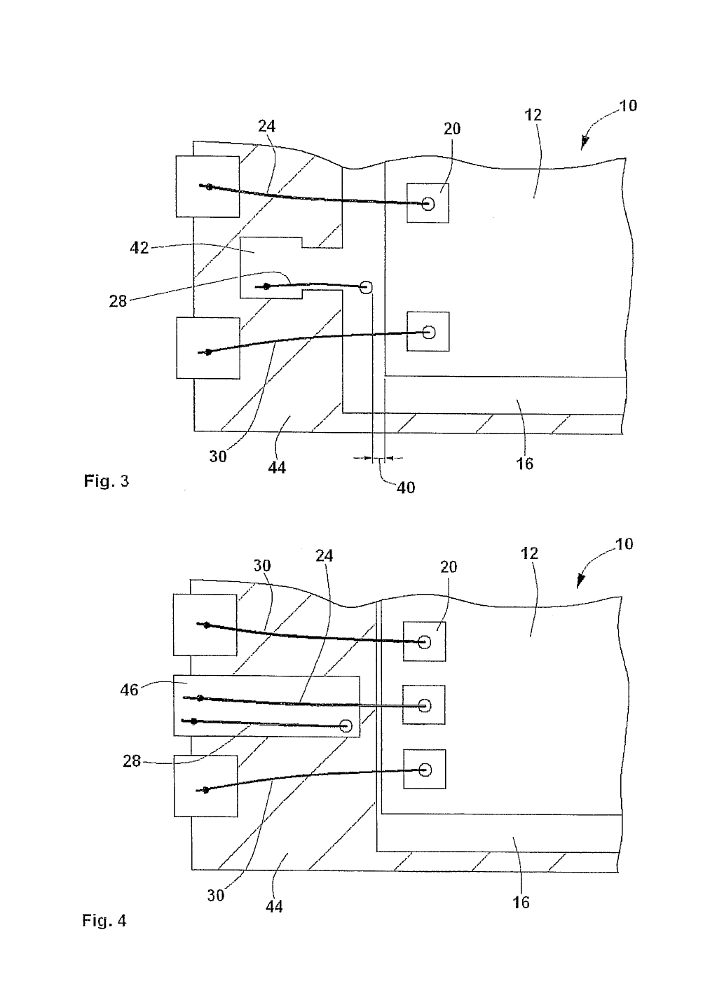

It is provided in the embodiment in FIG. 3 that at reference potential area 16 an outwardly projecting contact reed section 42 is provided, which acts as the base for shielding bonding wire 28. In contrast to the embodiment of FIGS. 1 and 2, contact reed section 42 is not routed as a contact reed outward from the potting compound 44 and also does not act as a bonding surface for reference potential bonding wire 24. Rather, contact reed section 42 is provided exclusively for forming a short-circuit loop with shielding bonding wire 28 and can have an electric potential different from the electric potential of reference potential bonding wire 24 or signal bonding wire 30.

In the embodiment in FIG. 4, reference potential bonding wire 24 and shielding bonding wire 28 are applied to a mutual elongated shielding contact reed 46, which is not connected to reference potential area 16. Therewith, an electric reference potential different from that at reference potential bonding wire 24 can be applied at integrated circuit 12 with its underside 14, which is applied in an electrically conductive manner to reference potential area 16. It is critical that the shielding bonding wire is assigned to reference potential bonding wire 24 in the immediate vicinity and that shielding contact reed 46 extends from an outer edge of the semiconductor component to shortly before integrated circuit 12, so that a substantially parallel course of shielding bonding wire 28 over as long a length as possible of reference potential bonding wire 24 can be assured.

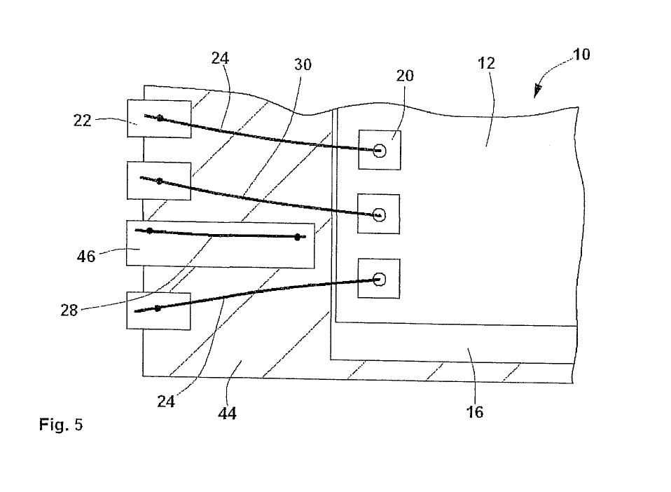

In the embodiment in FIG. 5, shielding bonding wire 28 is bonded to a separately made shielding contact reed 46 and is made as a wedge-wedge bonding connection to be able to realize the shortest distance possible to integrated circuit 12. The electromagnetic pulses transmitted by the directly adjacently disposed signal bonding wire 30 are coupled to an overwhelming proportion into shielding bonding wire 28 and there converted to heat in the short-circuit loop and thus influence the particular adjacent reference potential bonding wires 24 only to a small extent.

In an embodiment of the invention, not shown in greater detail, the integrated circuit is produced using silicon-on-oxide (SOI) technology. That is to say, the electric components (transistors, resistors, capacitors, etc.) of the integrated circuit are realized in a first, top silicon layer. This first silicon layer is isolated from a second silicon layer, also called a support wafer or handle wafer, by a thin oxide layer. The support wafer is glued in fact in an electrically conductive manner to the reference potential area, but because of the oxide layer it is connected only capacitively to the electric components, so that a connection of the electric components to the reference potential area is very high-impedance. For high-frequency signals, the oxide layer acts like a dielectric of a large capacitor, however, so that the integrated circuit for HF disturbances is virtually at the reference potential.

In an integrated circuit (not shown in greater detail), made as a semiconductor component for a LIN bus system, both the “interfering” bonding wire and the “interfered-with” bonding wire are made as ground wires and have the same reference potential. The LIN bus current flows through the “interfering” ground bonding wire. The second ground bonding wire is provided as a general signal ground of the integrated circuit (for, e.g., voltage reference, clock generator, etc.). In the case of electromagnetic disturbances in the LIN bus from outside, a large high-frequency current from the LIN bus flows through the integrated circuit and then through the first ground bonding wire. This induces a voltage in the second ground bonding wire, so that the signal ground of the integrated circuit can be greatly disturbed and malfunction of the integrated circuit may occur.

Because in standard LIN semiconductor components there is typically only one contact reed for ground, both ground bonding wires must be bonded of necessity closely next to each other to this contact reed. As a result, a high magnetic coupling between these ground bonding wires exists, which can be damped by the shielding bonding connection(s).

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor component for a bus system, the semiconductor component comprising:
an integrated circuit, which on a top side has a plurality of terminal pads for coupling and/or decoupling electrical signals;
a plurality of electrically conductive contact reeds, which are electrically connected at least partially by connecting bonding wires to respectively assigned terminal pads of the integrated circuit; and
a shielding bonding wire provided adjacent to a connecting bonding wire, the shielding bonding wire being disposed with both ends on a uniform electric potential or on one of the contact reeds.

2. The semiconductor component according to claim 1, wherein the shielding bonding wire and the connecting bonding wire are disposed on a mutual contact reed.

3. The semiconductor component according to claim 1, wherein the shielding bonding wire, at least in sections, runs within outer cylinder sections, which are disposed concentrically around the reference potential bonding wire and have a radius that are at most 6 times that of the bonding wire radius, at most 4.5 times that of the bonding wire radius, or at most 3.5 times that of the bonding wire radius.

4. The semiconductor component according to claim 3, wherein the shielding bonding wire runs at least over 50% of its length, over at least 75% of its length, or over at least 85% of its length within the outer cylinder sections of the connecting bonding wire.

5. The semiconductor component according to claim 1, wherein a first bonding connection of the shielding bonding wire is disposed directly adjacent to a bonding connection of the shielding bonding wire, particularly in a surrounding area around the connecting bonding wire, with a radius smaller than a 6-fold bonding wire radius.

6. The semiconductor component according to claim 1, wherein a second bonding connection of the shielding bonding wire is disposed directly adjacent to the integrated circuit, particularly at a distance less than 5-fold of the bonding wire radius, at a distance from an outer edge of the integrated circuit.

7. The semiconductor component according to claim 1, wherein the shielding bonding wire proceeding from the bonding connection adjacent to the integrated circuit runs at least substantially perpendicular to the reference potential area and is bent at a level of the connecting bonding wire with a bending radius, particularly at least almost with a minimal bonding wire bending radius, in such a way that it runs substantially parallel to the connecting bonding wire up to contact reed.

8. The semiconductor component according to claim 1, further comprising:
a first terminal pad of the integrated circuit being provided to supply a reference potential to a reference potential line of the integrated circuit,
wherein the integrated circuit is applied to an electrically conductive reference potential area,
wherein, proceeding from a reference potential contact reed, a reference potential bonding wire is routed to the first terminal pad connected to the first reference potential line, and
wherein, adjacent to the reference potential bonding wire, a shielding bonding wire is provided, which lies with both ends on the electric potential of the reference potential area.

9. The semiconductor component according to claim 8, wherein the reference potential area and the reference potential contact reed are made as a single piece.

10. The semiconductor component according to claim 1, wherein, the integrated circuit has a plurality of connecting bonding wires, each of which is assigned at least one shielding bonding wire.

11. The semiconductor component according to claim 1, wherein a connecting bonding wire is assigned shielding bonding wires on both sides.

12. The semiconductor component according to claim 8, wherein, proceeding from the reference potential contact reed, two reference potential bonding wires are routed to different reference potential lines of the integrated circuit and wherein at least one shielding bonding wire runs between the adjacent reference potential bonding wires.

13. The semiconductor component according to claim 1, wherein the bus system is a LIN bus system.
